(19) United States
(12) Patent Application Publication
(10) Pub. No.: US 2026/0367169 A1
(43) Pub. Date: Nov. 19, 2026

(54) METHOD FOR DETERMINING AN ELECTRIC VEHICLE BATTERY HEALTH LIFE TARGET OF AN ELECTRIC VEHICLE BATTERY

(71) Applicant: GM Global Technology Operations LLC, Detroit, MI (US)

(72) Inventors: Ryan Patrick Hickey, New York, NY (US); Matthew Edward Gilbert-Eyres, Rochester Hills, MI (US); Russell A. Patenaude, Macomb Township, MI (US)

(21) Appl. No.: 19/207,981

(22) Filed: May 14, 2025

(51) Int. Cl. G01R 31/392; B60L 53/66; G01R 31/367; G07C 5/04; H01M 10/44; H01M 10/48

(52) U.S. Cl. CPC G01R 31/392; B60L 53/66; G01R 31/367; G07C 5/04; H01M 10/44; H01M 10/48; B60L 2240/545; B60L 2240/547; B60L 2240/549; H01M 2220/20

(57) ABSTRACT

A method for determining an electric vehicle battery health life target of an electric vehicle battery includes a user inputting a desired battery health target input, a plurality of electric vehicle sensors of an electric vehicle having the electric vehicle battery collecting a plurality of charging condition data and driving condition data, and determining a projected battery health degradation and projected remaining battery health life of the electric vehicle battery. When the projected remaining battery health life is less than the desired battery health target input, the user may then decide to set the electric vehicle battery health life target to the projected remaining battery health life or set the electric vehicle battery health life target to the desired battery health target input while receiving suggestions of behaviors the user may take to lessen the reduction in performance capacity of the electric vehicle battery.

### INTRODUCTION

The present disclosure relates to determining an electric vehicle battery health life target of an electric vehicle battery.

Electric vehicles utilize electric vehicle batteries to receive and store electrical energy, releasing the electrical energy while in operation to power the electric vehicle. Each electric vehicle battery has an electric vehicle battery health life, which is the condition and performance capacity of the electric vehicle battery after use over a period of time since the first operational period of the electric vehicle battery. Over time, the electric vehicle battery health life decreases, as the condition of the electric vehicle battery is impacted by a plurality of charging conditions, a plurality of driving conditions, and a plurality of weather conditions, leading to a reduced performance capacity. A user of the electric vehicle generally has no input in determining the electric vehicle battery health life of the electric vehicle battery.

Thus, while current electric vehicle batteries achieve their intended purpose, there is a need for a new and improved system and method for determining an electric vehicle battery health life target of the electric vehicle battery.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method for determining a battery health life target of an electric vehicle battery. The method also includes receiving a desired battery health life input for the electric vehicle battery. The method also includes charging the electric vehicle battery in an electric vehicle. The method also includes collecting a plurality of charging condition data using a plurality of vehicle sensors in the electric vehicle while charging the electric vehicle battery. The method also includes operating the electric vehicle using power from the electric vehicle battery. The method also includes collecting a plurality of driving condition data using the plurality of vehicle sensors while operating the electric vehicle. The method also includes determining a projected battery health degradation of the electric vehicle battery based on the plurality of driving condition data, the plurality of charging condition data, and a plurality of battery life database data stored in the electric vehicle. The method also includes determining a projected remaining battery health life target of the electric vehicle battery based on the projected battery health degradation of the electric vehicle battery. The method also includes comparing the projected remaining battery health life target of the electric vehicle battery to the desired battery health target input. The method also includes determining the projected remaining battery health life target of the electric vehicle battery is shorter than the desired battery health life input based on the comparison of the projected remaining battery health life target and the desired battery health life input. The method also includes indicating the projected remaining battery health life target of the electric vehicle battery is shorter than the desired battery health life input. The method also includes receiving a battery health target risk input based on the indication that the projected remaining battery health life target of the electric vehicle battery is shorter than the desired battery health life input. The method also includes determining the battery health life target of the electric vehicle battery is the projected remaining battery health life target of the electric vehicle battery based on the received battery health target risk input. Other embodiments of this aspect include corresponding computer systems, apparatus, and computer programs recorded on one or more computer storage devices, each configured to perform the actions of the methods.

Implementations may include one or more of the following features. The method may include determining the desired battery health life input based on a plurality of desired battery health life input arbitrary preferences of a user. Determining the desired battery health life input based on the plurality of desired battery health life input arbitrary preferences of the user further may include inputting the desired battery health life input into a human-machine interface connected to the electric vehicle. Collecting the plurality of charging condition data using the plurality of vehicle sensors while charging the electric vehicle battery further may include collecting the plurality of charging condition data using the plurality of vehicle sensors having a plurality of temperature sensors, a plurality of voltage sensors, and a plurality of current sensors. Collecting a plurality of driving condition data using the plurality of vehicle sensors while operating the electric vehicle further may include collecting the plurality of driving condition data using the plurality of vehicle sensors having a plurality of temperature sensors, a plurality of accelerometers, a plurality of propulsion load sensors, and a location sensor. The method may include determining the projected remaining battery health life target of the electric vehicle battery is longer than or equal to the desired battery health life input based on the comparison of the projected remaining battery health life target and the desired battery health life input. The method may include determining the battery health life target of the electric vehicle battery is the desired battery health life input based on the determination that the projected remaining battery health life target of the electric vehicle battery is longer than or equal to the desired battery health life input. The method may include indicating the battery health life target of the electric vehicle battery is the desired battery health life input. Indicating the battery health life target of the electric vehicle battery is the desired battery health life input further may include indicating the battery health life target of the electric vehicle battery is the desired battery health life input via a human-machine interface connected to the electric vehicle. Indicating the projected remaining battery health life target of the electric vehicle battery is shorter than the desired battery health life input further may include indicating the projected remaining battery health life target of the electric vehicle battery is shorter than the desired battery health life input via a human-machine interface connected to the electric vehicle. The method may include determining the battery health target risk input based on a plurality of battery health target risk arbitrary preferences of a user. Determining the battery health target risk input based on the plurality of battery health target risk arbitrary preferences of the user further may include the user determining that the battery health target risk input is either true or false. Determining the battery health life target of the electric vehicle battery is the projected remaining battery health life target of the electric vehicle battery based on the received battery health target risk input further may include determining the battery health life target of the electric vehicle battery is the projected remaining battery health life target of the electric vehicle battery when the received battery health target risk input is true. The method may include determining the battery health life target of the electric vehicle battery to be the desired battery health life input for the electric vehicle battery when the received battery health target risk input is false. The method may include providing a plurality of user behavior data via a human-machine interface connected to the electric vehicle based on the plurality of driving condition data and the plurality of charging condition data when the battery health target risk input is false. The method may include suggesting techniques to improve the projected remaining battery health life target of the electric vehicle battery via the human-machine interface based on the plurality of user behavior data. The method may include limiting a plurality of functionalities of the electric vehicle based on the suggested techniques to improve the projected remaining battery health life target of the electric vehicle battery. Determining the battery health target risk input based on the plurality of battery health target risk arbitrary preferences of the user further may include inputting the battery health target risk input into a human-machine interface connected to the electric vehicle. Implementations of the described techniques may include hardware, a method or process, or computer software on a computer-accessible medium.

One general aspect includes a method for determining a battery health life target of an electric vehicle battery. The method also includes receiving a desired battery health life input for the electric vehicle battery. The method also includes charging the electric vehicle battery in an electric vehicle. The method also includes collecting a plurality of charging condition data using a plurality of vehicle sensors in the electric vehicle while charging the electric vehicle battery. The method also includes operating the electric vehicle using power from the electric vehicle battery. The method also includes collecting a plurality of driving condition data using the plurality of vehicle sensors while operating the electric vehicle. The method also includes calculating a projected battery health degradation of the electric vehicle battery based on the plurality of driving condition data, the plurality of charging condition data, and a plurality of battery life database data stored in the electric vehicle. The method also includes calculating a projected remaining battery health life target of the electric vehicle battery based on the projected battery health degradation of the electric vehicle battery. The method also includes comparing the projected remaining battery health life target of the electric vehicle battery to the desired battery health target input. The method also includes determining the projected remaining battery health life target of the electric vehicle battery is longer than or equal to the desired battery health life input based on the comparison of the projected remaining battery health life target and the desired battery health life input. The method also includes determining the battery health life target of the electric vehicle battery is the desired battery health life input based on the determination that the projected remaining battery health life target of the electric vehicle battery is longer than or equal to the desired battery health life input. Other embodiments of this aspect include corresponding computer systems, apparatus, and computer programs recorded on one or more computer storage devices, each configured to perform the actions of the methods.

One general aspect includes a method for determining a battery health life target of an electric vehicle battery. The method also includes receiving a desired battery health life input for the electric vehicle battery. The method also includes charging the electric vehicle battery in an electric vehicle. The method also includes collecting a plurality of charging condition data using the plurality of vehicle sensors while charging the electric vehicle battery. The method also includes operating the electric vehicle using power from the electric vehicle battery. The method also includes collecting a plurality of driving condition data using the plurality of vehicle sensors while operating the electric vehicle. The method also includes calculating a projected battery health degradation of the electric vehicle battery based on the plurality of driving condition data, the plurality of charging condition data, and a plurality of battery life database data stored in the electric vehicle. The method also includes calculating a projected remaining battery health life target of the electric vehicle battery based on the projected battery health degradation of the electric vehicle battery. The method also includes comparing the projected remaining battery health life target of the electric vehicle battery to the desired battery health target input. The method also includes determining the projected remaining battery health life target of the electric vehicle battery is shorter than the desired battery health life input based on the comparison of the projected remaining battery health life target and the desired battery health life input. The method also includes indicating the projected remaining battery health life target of the electric vehicle battery is shorter than the desired battery health life input. The method also includes determining the battery health target risk input based on a plurality of battery health target risk arbitrary preferences of a user where the battery health target risk input is either true or false. The method also includes receiving the battery health target risk input based on the indication that the projected remaining battery health life target of the electric vehicle battery is shorter than the desired battery health life input. The method also includes providing a plurality of user behavior data via a human-machine interface connected to the electric vehicle based on the plurality of driving condition data and the plurality of charging condition data when the battery health target risk input is false. The method also includes suggesting techniques to improve the projected remaining battery health life target of the electric vehicle battery via the human-machine interface based on the plurality of user behavior data. The method also includes determining the battery health life target of the electric vehicle battery is the desired battery health life input of the electric vehicle battery based on the received battery health target risk input. Other embodiments of this aspect include corresponding computer systems, apparatus, and computer programs recorded on one or more computer storage devices, each configured to perform the actions of the methods.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for determining an electric vehicle battery health life target of an electric vehicle battery according to an exemplary embodiment;

FIG. 2A is a first part of a flowchart of a method for determining the battery health life of the electric vehicle battery according to an exemplary embodiment; and

FIG. 2B is a second part of a flowchart of a method for determining the battery health life of the electric vehicle battery according to an exemplary embodiment.

### DETAILED DESCRIPTION

The following description is merely exemplary in nature and is not intended to limit the present disclosure, application, or uses.

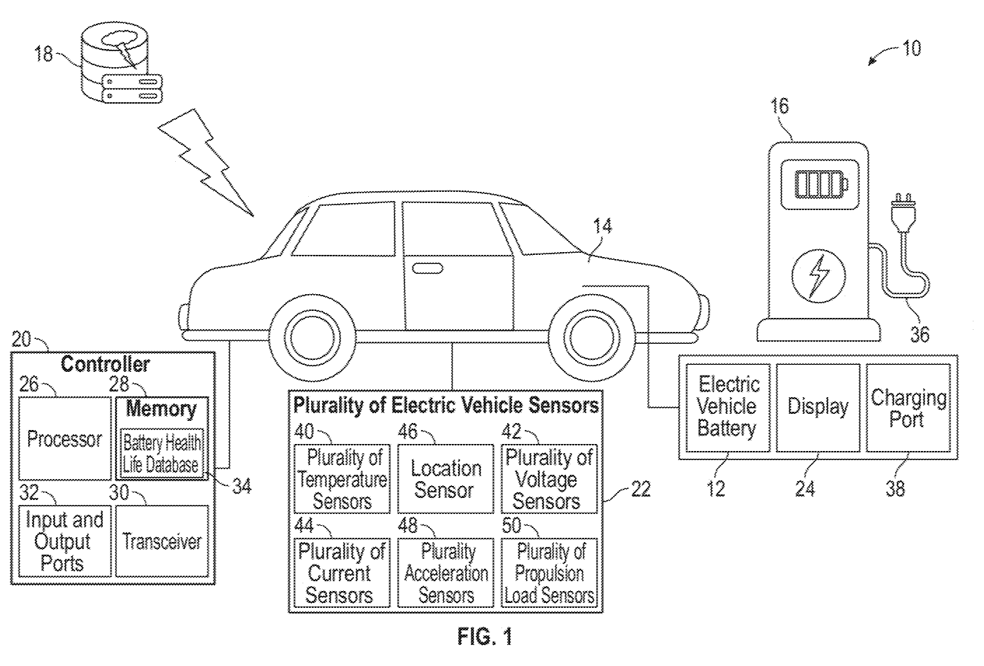

Referring to FIG. 1, a schematic diagram of a system 10 for determining an electric vehicle battery health life target of an electric vehicle battery 12 is shown. The system 10 generally includes an electric vehicle 14, a charging station 16, and a weather service 18.

The electric vehicle 14 is a land vehicle such as a car, truck, etc. that can be operated by a user or by an autonomous driving module. The electric vehicle 14 may have various levels of driving automation, including Level Five, Level Four, Level Three, and Level Two automation. For example, a Level Five system indicates “full automation,” referring to the full-time performance by an automated driving system of aspects of the dynamic driving task under a number of roadway and environmental conditions that can be managed by a human driver. A Level Four system indicates “high automation,” referring to the driving mode-specific performance by an automated driving system of aspects of the dynamic driving task, even if a human driver does not respond appropriately to a request to intervene. In Level Three vehicles, the vehicle systems perform the entire dynamic driving task (DDT) within the area that it is designed to do so. The vehicle operator is only expected to be responsible for the DDT-fallback when the electric vehicle 14 essentially “asks” the driver to take over if something goes wrong or the vehicle is about to leave the zone where it is able to operate. In Level Two vehicles, systems provide steering, brake/acceleration support, lane centering, and adaptive cruise control. However, even if these systems are activated, the vehicle operator at the wheel must be driving and constantly supervising the automated features. The electric vehicle 14 may include various actuator devices (not shown) used to achieve the above-described levels of automation. The actuator devices control one or more vehicle features including, but not limited to, a propulsion system, a transmission system, a steering system, and a brake system (not shown). In various embodiments, the vehicle features may further include interior and/or exterior vehicle features such as, but are not limited to, doors, a trunk, and cabin features such as air, music, lighting, etc. In the particular example provided in FIG. 1, the electric vehicle 14 includes a controller 20, the electric vehicle battery 12, a plurality of electric vehicle sensors 22, and a display 24.

The controller 20 is a non-generalized, electronic control device having a preprogrammed digital computer or processor 26, a memory 28, a transceiver 30, and a plurality of input and output ports 32. The processor 26 may be a custom made or commercially available processor, a central processing unit (CPU), a graphics processing unit (GPU), an auxiliary processor among several processors associated with the controller 20, a semiconductor-based microprocessor (in the form of a microchip or chip set), a microprocessor, a combination thereof, or generally a device for executing instructions. The memory 28 is used to store data such as control logic, software applications, instructions, computer code, data, lookup tables, etc. The memory 28 includes any type of medium capable of being accessed by a computer, such as read only memory (ROM), random access memory (RAM), a hard disk drive, a compact disc (CD), a digital video disc (DVD), or any other type of memory. The memory 28 also includes a battery health life database 34, which stores a plurality of database data having a plurality of stored charging condition data, a plurality of stored driving condition data, and stored weather data received from the weather service 18 (as explained in greater detail below). A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device. Computer code includes any type of program code, including source code, object code, and executable code. The processor 26 is configured to execute the code or instructions.

The transceiver 30 is configured to wirelessly communicate with a hotspot using Wi-Fi protocols under IEEE 802.11x standards. The transceiver 30 is also configured to wirelessly communicate using cellular data communication under GSMA standards, such as SGP.02, SGP.22, SGP.32 and the like. Suitably, the electric vehicle 14 may further include an embedded universal integrated circuit card (eUICC) configured to store at least one cellular connectivity configuration profile, for example, an embedded subscriber identity module (eSIM) profile. The transceiver 30 is further configured to communicate via a personal area network (e.g., BLUETOOTH), near-field communication (NFC), and/or any additional type of radiofrequency communication.

The plurality of input and output ports 32 receive incoming data from the plurality of electric vehicle sensors 22 and communicate the incoming data to the processor 26. The plurality of input and output ports 32 also receive outgoing data from the processor 26 and communicate the outgoing data to the plurality of electric vehicle sensors 22. The plurality of input and output ports 32 are configured to wirelessly communicate with the plurality of electric vehicle sensors 22 via the transceiver 30 and are also configured to communicate with the plurality of electric vehicle sensors 22 through a Universal Serial Bus (USB) wired connection.

The controller 20 may further include one or more applications. The application is a software program configured to perform a specific function or set of functions. The applications may include one or more computer programs, software components, sets of instructions, procedures, functions, objects, classes, instances, related data, or a portion thereof adapted for implementation in a suitable computer readable program code. The applications may be stored within the memory 28 or in additional or separate memory.

The controller 20 is in electrical communication with the plurality of electric vehicle sensors 22. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 20 are within the scope of the present disclosure.

The electric vehicle battery 12 serves as the primary source of power for the electric vehicle 14 by storing electrical energy and supplying the electrical energy to an electric motor which drives the electric vehicle 14. The electric vehicle battery 12 may be recharged by the user connecting a charging cable 36 of the charging station 16 to a charging port 38 of the electric vehicle 14, allowing for the transfer of the electrical energy housed in the charging station 16 to the electric vehicle battery 12 of the electric vehicle 14. The electric vehicle battery 12 has an electric vehicle battery health life, the electric vehicle battery health life target, and a desired battery health target input. The electric vehicle battery health life is the condition and performance capacity of the electric vehicle battery 12 after use over a period of time since the first operational period of the electric vehicle battery 12. It should be appreciated that the electric vehicle battery health life has a starting value of a performance capacity of 100% remaining battery health life. The electric vehicle battery health life target is a period of time since the first operational period of the electric vehicle battery 12 in which the condition and performance capacity of the electric vehicle battery 12 allows the electric vehicle 14 to operate.

Over time, the electric vehicle battery health life decreases, as the condition of the electric vehicle battery 12 is impacted by a plurality of charging conditions, a plurality of driving conditions, and a plurality of weather conditions, leading to a reduced performance capacity. The reduced performance capacity of the electric vehicle battery 12 due to each operational period of the electric vehicle 14 is projected by the processor 26 and is referred to as a projected battery health degradation of the electric vehicle battery 12. The projected battery health degradation is determined using a machine-learning model based on a plurality of charging condition data based on the plurality of charging conditions, a plurality of driving condition data based on the plurality of driving conditions, weather condition data received from the weather service 18, and a plurality of database data. In the exemplary embodiment, the projected battery health degradation is represented as a period of time the performance capacity of the electric vehicle battery 12 has been diminished during the last operational period of the electric vehicle battery 12. In another exemplary embodiment, the projected battery health degradation may be represented as a percentage of the electric vehicle battery health life. In the exemplary embodiment, the projected battery health degradation can then be used to determine a projected remaining battery health life of the electric vehicle battery 12 based on subtracting the projected battery health degradation from the from the electric vehicle battery health life target.

It should be appreciated that the projected battery health degradation is a projection generated by the machine-learning model based on patterns identified within data received by the machine-learning model. Therefore, the projected battery health degradation may be updated to indicate a lessened reduction in performance capacity of the electric vehicle battery 12, and therefore a maintained electric vehicle battery health life, when the plurality of charging conditions, the plurality of driving conditions, and the plurality of weather conditions when the respective pluralities of conditions are preferred for the battery health life of the electric vehicle battery 12. The user of the electric vehicle 14 may engage in a plurality of behaviors for the plurality of charging conditions and the plurality of driving conditions that enhance or are beneficial for the battery health life of the electric vehicle battery 12. In a non-limiting example, the plurality of charging conditions may be preferred for the battery health life of the electric vehicle battery 12 when a charging rate utilized to charge the electric vehicle battery 12 is reduced (as explained in greater detail below). In a non-limiting list of examples, the plurality of driving conditions may be preferred or optimal for the battery health life of the electric vehicle battery 12 when an ambient temperature of the environment surrounding the electric vehicle 14 is within a preferred or optimal ambient temperature range (i.e. between 20 degrees Celsius and 45 degrees Celsius), when a battery temperature of the electric vehicle battery 12 is within a preferred or optimal battery temperature range (i.e. between 20 degrees Celsius and 45 degrees Celsius), when the electric vehicle 14 does not undergo a period of frequent rapid acceleration, and when a torque value generated by an electric motor of the electric vehicle 14 does not exceed a torque value threshold.

The plurality of charging conditions are conditions that may impact the battery health life of the electric vehicle battery 12 while the electric vehicle 14 is charging. In a non-limiting list of examples, the plurality of charging conditions may include a charging rate of the electric vehicle 14 based on a voltage and current of a charging circuit of the electric vehicle 14 and the temperature of the electric vehicle battery 12. The plurality of driving conditions are conditions that may impact the battery health life of the electric vehicle 14 from the environment surrounding the electric vehicle 14 and the operation of the electric vehicle 14. In a non-limiting list of examples, the plurality of driving conditions may include the ambient temperature of the environment surrounding the electric vehicle 14, the acceleration of the electric vehicle 14, and the propulsion load of the electric vehicle 14. The plurality of weather conditions are conditions of the environment surrounding the electric vehicle 14 received from the weather service 18 (as further explained below).

The desired battery health target input is a target input entered by a user of the electric vehicle 14 via a human-machine interface (i.e. the display 24) that indicates to the controller 20 the period of time the user desires the electric vehicle battery 12 to be used to power the electric vehicle 14. In a non-limiting list of examples, the desired battery health target input may be expressed as a period of time in days, months, and years. It should be appreciated that the desired battery health target input is a target based on arbitrary preferences of the user and does not determine the electric vehicle battery health life, the projected battery health degradation, or the projected remaining battery health life.

The plurality of electric vehicle sensors 22 are located within the electric vehicle 14 and are used to acquire a plurality of charging condition data of the electric vehicle 14 based on the plurality of charging conditions and a plurality of driving condition data based on the plurality of driving conditions. In an exemplary embodiment, the plurality of electric vehicle sensors 22 has a plurality of temperature sensors 40, a plurality of voltage sensors 42, a plurality of current sensors 44, a location sensor 46, a plurality of acceleration sensors 48, and a plurality of propulsion load sensors 50.

The plurality of temperature sensors 40 are located throughout the electric vehicle 14 and around the electric vehicle battery 12. The plurality of temperature sensors 40 receive ambient temperature data from the environment surrounding the electric vehicle 14 and battery temperature data from the electric vehicle battery 12. The ambient temperature data and the battery temperature data are then communicated to the processor 26 to assist in determining a projected battery health degradation of the electric vehicle battery 12 and to assist in determining the charging rate utilized to charge the electric vehicle 14 while the electric vehicle 14 is charging respectively. In a non-limiting list of examples, the charging rate utilized to charge the electric vehicle 14 may be Level 1 Charging, Level 2 Charging, and DC Fast Charging (DCFC).

It should be appreciated that the processor 26 may generally determine the charging rate utilized is Level 1 Charging when the temperature data indicates the temperature of the electric vehicle battery 12 is between 20 and 30 degrees Celsius. It should be further appreciated that the processor 26 may generally determine the charging rate utilized is Level 2 Charging when the temperature data indicates the temperature of the electric vehicle battery 12 is between 30 and 40 degrees Celsius. It should also be appreciated that the processor 26 may generally determine the charging rate utilized is DCFC when the temperature data indicates the temperature of the electric vehicle battery 12 is between 40 and 60 degrees Celsius.

The plurality of voltage sensors 42 are located throughout the electric vehicle 14 and measure the voltage at various points along the charging circuit of the electric vehicle 14 to monitor the voltage running through the charging circuit while the electric vehicle 14 is charging. The plurality of voltage sensors 42 receive voltage data based on a voltage running through the charging circuit while the electric vehicle 14 is charging. The voltage data is then communicated to the processor 26 to assist in determining the charging rate utilized to charge the electric vehicle 14. In a non-limiting list of examples, the plurality of voltage sensors 42 may be located adjacent to the charging port 38 and the electric vehicle battery 12.

It should be appreciated that the processor 26 may generally determine the charging rate utilized is Level 1 Charging when the voltage data indicates the voltage along the charging circuit is around 120 volts (V) in alternating current (AC) voltage. It should be further appreciated that the processor 26 may generally determine the charging rate utilized is Level 2 Charging when the voltage data indicates the voltage along the charging circuit is around 240V in AC voltage. It should also be appreciated that the processor 26 may generally determine the charging rate utilized is DCFC when the voltage data indicates the voltage along the charging circuit is around 400V to 800V in direct current (DC) voltage.

The plurality of current sensors 44 are located throughout the electric vehicle 14 and measure the current at various points along the charging circuit of the electric vehicle 14 to monitor the current running through the charging circuit while the electric vehicle 14 is charging. The plurality of current sensors 44 receive current data based on a current running through the charging circuit while the electric vehicle 14 is charging. The current data is then communicated to the processor 26 to assist in determining a charging rate utilized to charge the electric vehicle 14. In a non-limiting list of examples, the plurality of current sensors 44 may be located adjacent to the charging port 38 and the electric vehicle battery 12.

It should be appreciated that the processor 26 may generally determine the charging rate utilized is Level 1 Charging when the current data indicates the current along the charging circuit is between 12 and 16amperes (amps). It should be further appreciated that the processor 26 may generally determine the charging rate utilized is Level 2 Charging when the current data indicates the current along the charging circuit is between 12 and 80 amps. It should also be appreciated that the processor 26 may generally determine the charging rate utilized is DCFC when the current data indicates the current along the charging circuit is between 50 and 300 amps.

The location sensor 46 is located within the electric vehicle 14 and receives positional data of the environment surrounding the electric vehicle 14. The positional data is then communicated to the weather service 18 via the transceiver 30. In a non-limiting list of examples, the positional data may be represented as a set of geographic coordinates in a two-dimensional cartesian coordinate system having a latitude and a longitude, a set of geographic coordinates in a three-dimensional cartesian coordinate system having a latitude, longitude, and altitude, a set of Universal Transverse Mercator (UTM) coordinates having an easting coordinate and a northing coordinate, a set of State Plane Coordinates (SPC), and a set of polar coordinates.

The plurality of acceleration sensors 48 are located throughout the electric vehicle 14 and receive acceleration data of the electric vehicle 14 based on the acceleration of the electric vehicle 14 at a moment in time. In a non-limiting list of examples, the plurality of acceleration sensors 48 may have capacitive accelerometers, piezoelectric accelerometers, piezoresistive accelerometers, optical accelerometers, and servo accelerometers. The acceleration data is then communicated to the processor 26 to assist in determining the projected battery health degradation of the electric vehicle battery 12.

The plurality of propulsion load sensors 50 are located throughout the electric vehicle 14 and receive propulsion load data of the electric vehicle 14 based on the torque value generated by the electric motor of the electric vehicle 14. In a non-limiting list of examples, the plurality of propulsion load sensors 50 may have torque sensors, strain gauge sensors, and hall effect sensors. The propulsion load data is then communicated to the processor 26 to assist in determining the projected battery health degradation of the electric vehicle battery 12.

The display 24 is a screen that is located within the electric vehicle 14 that has a human-machine interface that presents the battery health life of the electric vehicle 14 and the temperature data, positional data, acceleration data, and propulsion load data received by the plurality of electric vehicle sensors 22. The display 24 also allows the user to configure the electric vehicle 14, and run the applications included in the controller 20.

The charging station 16 is equipment that supplies electrical energy for the purpose of recharging the electric vehicle battery 12 of the electric vehicle 14. The charging station 16 has the charging cable 36, which is a medium that carries the electrical energy from the charging station 16 to the charging port 38 of the electric vehicle 14. In a non-limiting list of examples, the charging station 16 may be a Level 1 Charging Station, a Level 2 Charging Station, a Direct Current (DC) Fast Charging Station, or a General Motors (GM) Energy Home Charger.

The weather service 18 is a service used to communicate weather condition data based on the plurality of weather conditions of a location of the electric vehicle 14, which is based on the positional data to the processor 26. In an exemplary embodiment, the weather service 18 is a computerized database that may communicate the weather data via satellite, a cellular network, or a local area network. The weather data may have, in a non-limiting list of examples, information regarding the temperature, humidity, wind chill, wind speed, and precipitation of the location of the electric vehicle 14.

In an exemplary embodiment where the electric vehicle 14 belongs to a fleet of electric vehicles, the user may set limits on the operation of the electric vehicle 14 when the measurements of the plurality of charging conditions and the plurality of driving conditions exceed a plurality of limiting thresholds based on the arbitrary preferences of the user in order to maintain the battery health life of the electric vehicle battery 12. In a non-limiting example, the user may set a maximum voltage of 240V in AC voltage and/or a maximum current of 80 amps that may be measured along the charging circuit to limit the charging rate of the electric vehicle 14 to Level 2 Charging and to prevent the charging rate of the electric vehicle 14 from rising to DCFC. In another non-limiting example, the user may set a maximum torque value threshold of the electric vehicle, which, when exceeded, the electric vehicle 14 will not continue operation. In another non-limiting example, the user may set a maximum ambient temperature threshold and/or a minimum ambient temperature threshold in which, when an ambient temperature of the environment surrounding the electric vehicle 14 falls above the maximum ambient temperature threshold and/or below the minimum ambient temperature threshold, the electric vehicle 14 will not continue operation. In another non-limiting example, the user may set a maximum battery temperature threshold and/or a minimum battery temperature threshold in which, when a temperature of the electric vehicle battery 12 falls above the maximum battery temperature threshold and/or below the minimum battery temperature threshold, the electric vehicle 14 will not continue operation. In another non-limiting example, the user may set a rapid acceleration threshold, where when the number of times the electric vehicle 14 accelerates rapidly within a period of time set by the user is larger than the rapid acceleration threshold, the electric vehicle 14 will not accelerate.

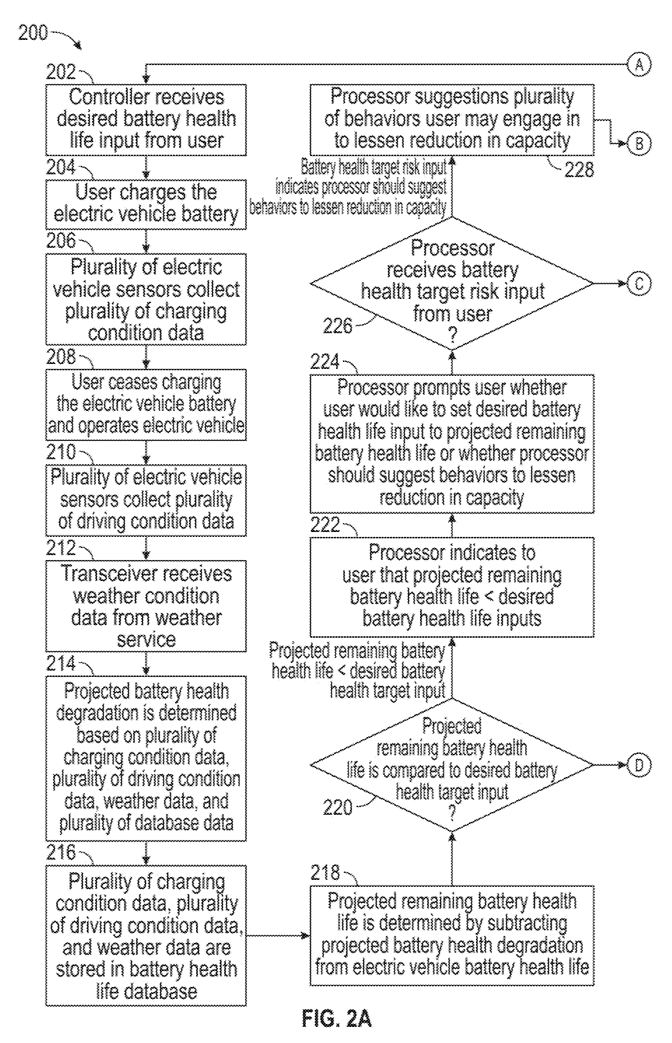

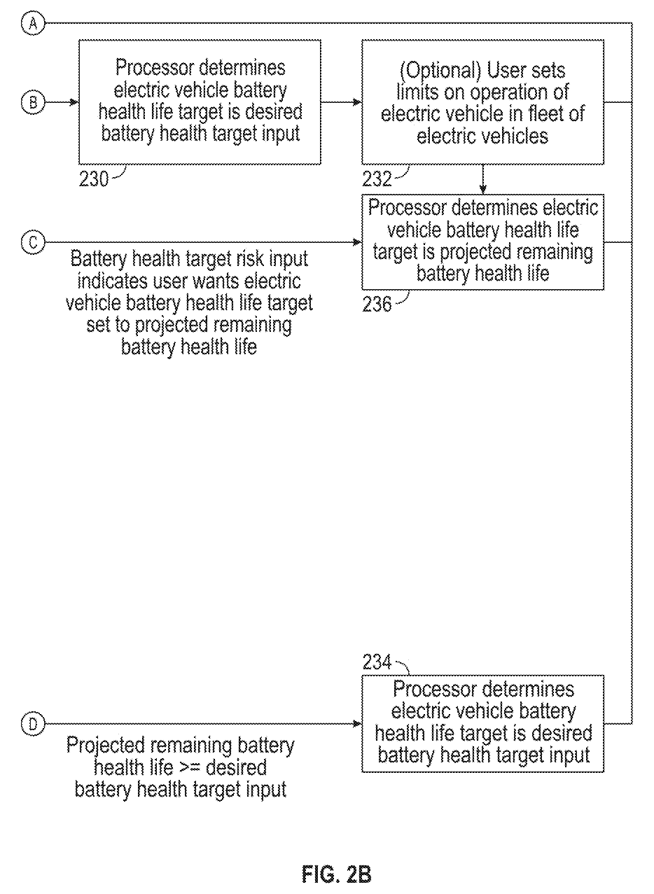

Referring to FIGS. 2A and 2B, a flowchart of a method for determining the battery health life of the electric vehicle battery 12 is generally indicated by reference number 200. The method 200 begins at step 202, where the controller 20 receives the desired battery health target input for the electric vehicle battery 12 from the user via the display 24. The method 200 then proceeds to step 204.

At step 204, the user charges the electric vehicle battery 12 of the electric vehicle 14 at the charging station 16 by connecting the charging cable 36 to the charging port 38 of the electric vehicle 14. The method 200 then proceeds to step 206.

At step 206, the plurality of electric vehicle sensors 22 collect the plurality of charging condition data while the electric vehicle battery 12 is charging based on the plurality of charging conditions and communicates the plurality of charging condition data to the processor 26. The method 200 then proceeds to step 208.

At step 208, the user ceases charging the electric vehicle battery 12 and operates the electric vehicle 14 using power from the electric vehicle battery 12. The method 200 then proceeds to step 210.

At step 210, the plurality of electric vehicle sensors 22 collect the plurality of driving condition data based on the plurality of driving conditions and communicates the plurality of driving condition data to the processor 26. The method 200 then proceeds to step 212.

At step 212, the transceiver 30 receives the weather condition data from the weather service 18 which is then communicated to the processor 26. The method 200 then proceeds to step 214.

At step 214, the plurality of charging condition data, the plurality of driving condition data, the weather data, and the plurality of database data from the battery health life database 34 are received by the processor 26 and are inputted into the machine-learning model to determine the projected battery health degradation of the electric vehicle battery 12. The method 200 then proceeds to step 216.

At step 216, the plurality of charging condition data, the plurality of driving condition data, and the weather data are stored in the battery health life database 34 as the plurality of stored charging condition data, the plurality of stored driving condition data, and the stored weather data respectively. The method 200 then proceeds to step 218.

At step 218, the result of subtracting the projected battery health degradation from the electric vehicle battery health life is used to determine the projected remaining battery health life of the electric vehicle battery 12. The method 200 then proceeds to step 220.

At step 220, the projected remaining battery health life of the electric vehicle battery 12 is compared to the desired battery health target input. When the projected remaining battery health life is less than the desired battery health target input, the method 200 then proceeds to step 222.

At step 222, the processor 26 indicates to the user via the display 24 that the projected remaining battery health life of the electric vehicle battery 12 is shorter than the desired battery health target input. The method 200 then proceeds to step 224.

At step 224, the processor 26 prompts the user via the display 24 whether the user would like to set the desired battery health target input to the projected remaining battery health life or whether the processor 26 should suggest behaviors that would lessen the reduction in performance capacity, and therefore maintain the electric vehicle battery health life, of the electric vehicle battery 12. The method 200 then proceeds to step 226.

At step 226, the processor 26 receives a battery health target risk input from the user via the display 24 that indicates whether the user would like to set the electric vehicle battery health life target to the projected remaining battery health life or whether the processor 26 should suggest behaviors that would lessen the reduction in performance capacity of the electric vehicle battery 12. It should be appreciated that the battery health target risk input is based on a plurality of desired battery health target input arbitrary preferences of the user. When the battery health target risk input indicates that the processor 26 should suggest behaviors that would lessen the reduction in performance capacity of the electric vehicle battery 12, the method 200 then proceeds to step 228.

At step 228, the processor 26 suggests the plurality of behaviors the user may engage in that may lessen the reduction in performance capacity of the electric vehicle battery 12 and therefore maintain the electric vehicle battery health life and the desired battery health target input via the display 24. The method 200 then proceeds to step 230.

At step 230, the processor 26 determines the electric vehicle battery health life target is the desired battery health target input. The method 200 then proceeds to step 232.

At step 232, when the electric vehicle 14 belongs to a fleet of electric vehicles, the user may set limits on the operation of the electric vehicle 14, including but not limited to the charging rate, the propulsion load, and acceleration of the electric vehicle 14. It should be appreciated that this step is only applicable when the electric vehicle 14 belongs to a fleet of electric vehicles and is therefore an optional step. The method 200 then proceeds to step 202.

Returning to step 220, when the projected remaining battery health life is greater than or equal to the desired battery health target input, the method 200 then proceeds to step 234.

At step 234, the processor 26 determines the electric vehicle battery health life target is the desired battery health target input. The method 200 then proceeds to step 202.

Returning to step 226, when the battery health target risk input indicates the user would like to set the electric vehicle battery health life target to the projected remaining battery health life, the method 200 then proceeds to step 236.

At step 236, the processor 26 determines the electric vehicle battery health life target is the projected remaining battery health life. The method 200 then proceeds to step 202.

The method 200 of the present disclosure offers several advantages. One such advantage is allowing the user to input the desired battery health target input for the processor 26 to consider while determining the projected remaining battery health life of the electric vehicle battery 12 to indicate the user when the projected remaining battery health life is less than the desired battery health target input. Another such advantage is allowing the user to input the battery health target risk input in order to set the electric vehicle battery health life target to the projected remaining battery health life or to receive suggestions on the plurality of behaviors the user may engage in that may lessen the reduction in performance capacity of the electric vehicle battery 12 and therefore maintain the electric vehicle battery health life and the desired battery health target input.

The description of the present disclosure is merely exemplary in nature and variations that do not depart from the gist of the present disclosure are intended to be within the scope of the present disclosure. Such variations are not to be regarded as a departure from the spirit and scope of the present disclosure.

1. A method for determining a battery health life target of an electric vehicle battery, the method comprising:
receiving, via a human-machine interface, a desired battery health target input for the electric vehicle battery, the desired battery health target input comprising a period of time indicating how long a user of the electric vehicle desires the electric vehicle battery to be used to power the electric vehicle;
charging the electric vehicle battery in the electric vehicle;
collecting a plurality of charging condition data using a plurality of vehicle sensors in the electric vehicle while charging the electric vehicle battery;
operating the electric vehicle using power from the electric vehicle battery;
collecting a plurality of driving condition data using the plurality of vehicle sensors while operating the electric vehicle;
determining a projected battery health degradation of the electric vehicle battery based on the plurality of driving condition data, the plurality of charging condition data, and a plurality of battery life database data stored in the electric vehicle;
determining a projected remaining battery health life target of the electric vehicle battery based on the projected battery health degradation of the electric vehicle battery;
comparing the projected remaining battery health life target of the electric vehicle battery to the period of time represented by the desired battery health target input;
determining that the projected remaining battery health life target of the electric vehicle battery is shorter than the period of time represented by the desired battery health target input based on the comparison of the projected remaining battery health life target and the period of time represented by the desired battery health target input;
displaying, via the human-machine interface, an indication that the projected remaining battery health life target of the electric vehicle battery is shorter than the period of time represented by the desired battery health target input;
receiving, via the human-machine interface, a battery health target risk input indicating that the battery health life target is to be the projected remaining battery health life target of the electric vehicle battery, the battery health target risk input being received based on the indication that the projected remaining battery health life target of the electric vehicle battery is shorter than the period of time represented by the desired battery health target input; and
determining that the battery health life target of the electric vehicle battery is the projected remaining battery health life target of the electric vehicle battery based on the received battery health target risk input.

2. The method of claim 1,wherein receiving the desired battery health target input further comprises receiving the desired battery health target input based on a plurality of desired battery health target input arbitrary preferences of the user.

3. The method of claim 2, wherein receiving the desired battery health target input based on the plurality of desired battery health target input arbitrary preferences of the user further comprises inputting the desired battery health target input into the human-machine interface, wherein the human-machine interface is connected to the electric vehicle.

4. The method of claim 1, wherein collecting the plurality of charging condition data using the plurality of vehicle sensors while charging the electric vehicle battery further comprises collecting the plurality of charging condition data using the plurality of vehicle sensors having a plurality of temperature sensors, a plurality of voltage sensors, and a plurality of current sensors.

5. The method of claim 1, wherein collecting a plurality of driving condition data using the plurality of vehicle sensors while operating the electric vehicle further comprises collecting the plurality of driving condition data using the plurality of vehicle sensors having a plurality of temperature sensors, a plurality of accelerometers, a plurality of propulsion load sensors, and a location sensor.

6. (canceled)

7. (canceled)

8. The method of claim 1, further comprising displaying, via the human-machine interface, an indication that the battery health life target of the electric vehicle battery is the projected remaining battery health life target of the electric vehicle battery.

9. (canceled)

10. The method of claim 1, wherein indicating the projected remaining battery health life target of the electric vehicle battery is shorter than the period of time represented by the desired battery health target input further comprises indicating the projected remaining battery health life target of the electric vehicle battery is shorter than the period of time represented by the desired battery health target input via a human-machine interface connected to the electric vehicle.

11. The method of claim 1,wherein receiving the battery health target risk input further comprises receiving the battery health target risk input based on a plurality of battery health target risk arbitrary preferences of a user.

12. The method of claim 11, wherein receiving the battery health target risk input based on the plurality of battery health target risk arbitrary preferences of the user further comprises displaying, via the human-machine interface, an indication that the electric vehicle battery health life target is set to the projected remaining battery health life or an indication of suggestions of behaviors that would maintain the period of time represented by the desired battery health target input.

13. The method of claim 11, wherein receiving the battery health target risk input based on the plurality of battery health target risk arbitrary preferences of the user further comprises inputting the battery health target risk input into the human-machine interface, wherein the human-machine interface is connected to the electric vehicle.

14. The method of claim 12, wherein determining that the battery health life target of the electric vehicle battery is the projected remaining battery health life target of the electric vehicle battery based on the received battery health target risk input further comprises determining that the battery health life target of the electric vehicle battery is the projected remaining battery health life target of the electric vehicle battery when the received battery health target risk input indicates the electric vehicle battery health life target should be set to the projected remaining battery health life.

15. The method of claim 12, further comprising determining that the battery health life target of the electric vehicle battery to be equal to the period of time represented by the desired battery health target input for the electric vehicle battery when the received battery health target risk input indicates the user should receive suggestions of behaviors that would maintain the period of time represented by the desired battery health target input.

16. The method of claim 12, further comprising providing a plurality of user behavior data via a human-machine interface connected to the electric vehicle based on the plurality of driving condition data and the plurality of charging condition data when the battery health target risk input indicates the user should receive suggestions of behaviors that would maintain the period of time represented by the desired battery health target input.

17. The method of claim 16, further comprising suggesting techniques to improve the projected remaining battery health life target of the electric vehicle battery via the human-machine interface based on the plurality of user behavior data.

18. The method of claim 17, further comprising limiting a plurality of functionalities of the electric vehicle based on the suggested techniques to improve the projected remaining battery health life target of the electric vehicle battery.

19. A method for determining a battery health life target of an electric vehicle battery, the method comprising:
receiving, via a human-machine interface, a desired battery health target input for the electric vehicle battery of an electric vehicle, the desired battery health target input comprising a period of time indicating how long a user of the electric vehicle desires the electric vehicle battery to be used to power the electric vehicle;
charging the electric vehicle battery in the electric vehicle;
collecting a plurality of charging condition data using a plurality of vehicle sensors in the electric vehicle while charging the electric vehicle battery;
operating the electric vehicle using power from the electric vehicle battery;
collecting a plurality of driving condition data using the plurality of vehicle sensors while operating the electric vehicle;
calculating a projected battery health degradation of the electric vehicle battery based on the plurality of driving condition data, the plurality of charging condition data, and a plurality of battery life database data stored in the electric vehicle;
calculating a projected remaining battery health life target of the electric vehicle battery based on the projected battery health degradation of the electric vehicle battery;
comparing the projected remaining battery health life target of the electric vehicle battery to the period of time represented by the desired battery health target input;
determining that the projected remaining battery health life target of the electric vehicle battery is longer than or equal to the period of time represented by the desired battery health target input based on the comparison of the projected remaining battery health life target and the period of time represented by the desired battery health target input; and
determining that the battery health life target of the electric vehicle battery is equal to the period of time represented by the desired battery health target input based on the determination that the projected remaining battery health life target of the electric vehicle battery is longer than or equal to the period of time represented by the desired battery health target input.

20. A method for determining a battery health life target of an electric vehicle battery, the method comprising:
receiving, via a human-machine interface, a desired battery health target input for the electric vehicle battery of an electric vehicle, the desired battery health target input comprising a period of time indicating how long a user of the electric vehicle desires the electric vehicle battery to be used to power the electric vehicle;
charging the electric vehicle battery in the electric vehicle;
collecting a plurality of charging condition data using a plurality of vehicle sensors of the electric vehicle while charging the electric vehicle battery;
operating the electric vehicle using power from the electric vehicle battery;
collecting a plurality of driving condition data using the plurality of vehicle sensors while operating the electric vehicle;
calculating a projected battery health degradation of the electric vehicle battery based on the plurality of driving condition data, the plurality of charging condition data, and a plurality of battery life database data stored in the electric vehicle;
calculating a projected remaining battery health life target of the electric vehicle battery based on the projected battery health degradation of the electric vehicle battery;
comparing the projected remaining battery health life target of the electric vehicle battery to the period of time represented by the desired battery health target input;
determining that the projected remaining battery health life target of the electric vehicle battery is shorter than the period of time represented by the desired battery health target input based on the comparison of the projected remaining battery health life target and the period of time represented by the desired battery health target input;
displaying, via the human-machine interface, an indication that the projected remaining battery health life target of the electric vehicle battery is shorter than the period of time represented by desired battery health target input;
determining a battery health target risk input based on a plurality of battery health target risk arbitrary preferences of a user wherein the battery health target risk input is either indicating the electric vehicle battery health life target should be set to the projected remaining battery health life or the user should receive suggestions of behaviors that would maintain the period of time represented by the desired battery health target input;
receiving, via the human-machine interface, the battery health target risk input indicating that the battery health life target is to be the projected remaining battery health life target of the electric vehicle battery, the battery health target risk input being received based on the indication that the projected remaining battery health life target of the electric vehicle battery is shorter than the period of time represented by the desired battery health target input;
providing a plurality of user behavior data via a human-machine interface connected to the electric vehicle based on the plurality of driving condition data and the plurality of charging condition data when the battery health target risk input indicates the user should receive suggestions of behaviors that would maintain the period of time represented by the desired battery health target input;
suggesting techniques to improve the projected remaining battery health life target of the electric vehicle battery via the human-machine interface based on the plurality of user behavior data; and
determining that the battery health life target of the electric vehicle battery is equal to the period of time represented by the desired battery health target input of the electric vehicle battery based on the received battery health target risk input.
